(19) United States
(12) Patent Application Publication
(10) Pub. No.: US 2018/0312965 A1
(43) Pub. Date: Nov. 1, 2018

(54) VAPOR DEPOSITION DEVICE

(71) Applicant: WUHAN CHINA STAR OPTOELECTRONICS TECHNOLOGY CO., LTD., Wuhan, Hubei (CN)

(72) Inventor: Junying MU, Wuhan, Hubei (CN)

(21) Appl. No.: 15/566,905

(22) PCT Filed: Jun. 9, 2017
(86) PCT No.: PCT/CN2017/087788

§ 371 Date: Oct. 16, 2017

(30) Foreign Application Priority Data
Apr. 26, 2017 (CN) 201710281681.7

(51) Int. Cl. C23C 14/54; C23C 14/24

(52) U.S. Cl. CPC C23C 14/542; H01L 51/001; C23C 14/246

(57) ABSTRACT

A vapor deposition device includes an evaporation section, a transmission pipe, and a vapor deposition section. The transmission pipe includes a first pipe, a second pipe, and a third pipe. An end of the first pipe is in communication with the evaporation chamber of the evaporation section. An end of the second pipe is in communication with the vapor deposition chamber of the vapor deposition section. The third pipe is in communication with another end of the first pipe and another end of the second pipe. A vapor pressure controlling component is disposed on the third pipe to control a vapor pressure of the evaporating vapor in the third pipe.

### FIELD OF THE INVENTION

The present disclosure relates to the field of manufacturing liquid crystal display panels, and more particularly to a vapor deposition device.

### BACKGROUND OF THE INVENTION

In today's information society, the importance of display devices is highly emphasized as a visual information transmission medium, but their requirements, such as being light weight, having a thinner profile, having low power consumption, being low cost, and having a higher picture quality should be satisfied in order to maintain their principal position in the future.

Organic light emitting diode (OLED) display technology, compared to current mainstream liquid crystal display technology, has the outstanding advantages of having a high contrast, a wide color gamut, being flexible and light weight, having a thin profile, low power consumption, and the like. In recent years, OLED display technology has gradually become popular in the area of mobile devices, such as smart phones, tablet computers, etc., flexible wearable devices such as smart watches and the like, large sized curved televisions, white light illumination devices, etc. It has strong growth.

OLED technology mainly includes vacuum evaporation technology based small molecule OLED technology and solution process based polymer OLED technology. Evaporation machines are the current main mass equipment for manufacturing small molecule OLED components. A core part of the equipment is an evaporation source device, which is divided into a point evaporation source device, a line evaporation source device, a surface evaporation source device, etc. The line evaporation source device is currently an important mass technology mainly divided into an integrated line evaporation source device and a conveying line evaporation source device.

When the evaporation source is in idle mode, temperature of each part of the evaporation source needs to be maintained to be equal to temperature of the normal coating mode, so that evaporation vapor goes outside, resulting in a large material loss and a decrease in material utilization.

Therefore, there are defects existing in the conventional technologies which need to be improved.

### SUMMARY OF THE INVENTION

An object of the present disclosure is to provide an improved vapor deposition device.

To achieve the above object, the present disclosure provides a vapor deposition device, including:

an evaporation section, a transmission pipe, and a vapor deposition section, wherein the evaporation section is configured to heat vapor deposition material to form evaporating vapor in an evaporation chamber of the evaporation section, the transmission pipe is configured to transmit the evaporating vapor formed in the evaporation chamber to a vapor deposition chamber of the vapor deposition section, and the vapor deposition section is configured to deposit the evaporating vapor accumulated in the vapor deposition chamber onto a substrate;

the transmission pipe including a first pipe, a second pipe, and a third pipe;

an end of the first pipe being in communication with the evaporation chamber of the evaporation section, wherein a first temperature controlling component is disposed on the first pipe for maintaining a constant temperature in the first pipe;

an end of the second pipe being in communication with the vapor deposition chamber of the vapor deposition section, wherein a second temperature controlling component is disposed on the second pipe for maintaining a constant temperature in the second pipe; and

the third pipe being in communication with another end of the first pipe and another end of the second pipe, a vapor pressure controlling component being disposed on the third pipe, wherein the vapor pressure controlling component is configured for controlling a vapor pressure of the evaporating vapor in the third pipe to decrease when switching from vapor deposition to idle, and the vapor pressure controlling component is configured for controlling the vapor pressure of the evaporating vapor in the third pipe to increase when switching from idle to vapor deposition.

In embodiments of the present disclosure, the vapor pressure controlling component includes a controller, a cooler, and a heater, the controller electrically connects to the cooler and the heater. The controller controls the cooler to decrease a temperature in the third pipe in order to decrease the vapor pressure of the evaporating vapor in the third pipe from a first vapor pressure value to a second vapor pressure value when switching from vapor deposition to idle, and the controller controls the heater to increase the temperature in the third pipe in order to increase the vapor pressure of the evaporating vapor in the third pipe from the second vapor pressure value to the first vapor pressure value when switching from idle to vapor deposition.

In embodiments of the present disclosure, the heater covers an outer wall of the third pipe, and the cooler covers the heater:

In embodiments of the present disclosure, there is a thermal insulating layer disposed between the cooler and the heater.

In embodiments of the present disclosure, the heater is an electric heating wire that coils around the third pipe.

In embodiments of the present disclosure, the cooler includes an overtube and a refrigerant, the overtube is sleeved on outside the thermal insulating layer, and a gap between an inner wall of the overtube and an outer wall of the thermal insulating layer accommodates the refrigerant.

In embodiments of the present disclosure, the overtube has an air inlet for allowing the refrigerant to flow in and an air outlet for allowing the refrigerant to flow outward.

In embodiments of the present disclosure, the overtube has a flow valve, the flow valve is disposed in the overtube for controlling a flow rate of the refrigerant in the overtube.

In embodiments of the present disclosure, the first pipe, the second pipe, and the third pipe are disposed coaxially and are cylindrical structures, and a width of a channel of the third pipe is less than widths of channels of the first pipe and the second pipe.

In embodiments of the present disclosure, the vapor deposition section has a wall, the wall has an injection port, and the injection port in communication with the vapor deposition chamber is disposed on the wall for injecting the evaporation vapor in the vapor deposition chamber to the substrate.

An embodiment of the present disclosure further provides another vapor deposition device, including:

an evaporation section, a transmission pipe, and a vapor deposition section, wherein the evaporation section is configured to heat vapor deposition material to form evaporating vapor in an evaporation chamber of the evaporation section, the transmission pipe is configured to transmit the evaporating vapor formed in the evaporation chamber to a vapor deposition chamber of the vapor deposition section, and the vapor deposition section is configured to deposit the evaporating vapor accumulated in the vapor deposition chamber onto a substrate;

the transmission pipe including a first pipe, a second pipe, and a third pipe;

an end of the first pipe being in communication with the evaporation chamber of the evaporation section, wherein a first temperature controlling component is disposed on the first pipe for maintaining a constant temperature in the first pipe;

an end of the second pipe being in communication with the vapor deposition chamber of the vapor deposition section, wherein a second temperature controlling component is disposed on the second pipe for maintaining a constant temperature in the second pipe;

the third pipe in communication with another end of the first pipe and another end of the second pipe, a vapor pressure controlling component being disposed on the third pipe, wherein the vapor pressure controlling component includes a controller, a cooler, and a heater, the controller electrically connects to the cooler and the heater, the heater covers an outer wall of the third pipe, and the cooler covers the heater; and

wherein the controller controls the cooler to decrease a temperature in the third pipe in order to decrease the vapor pressure of the evaporating vapor in the third pipe from a first vapor pressure value to a second vapor pressure value when switching from vapor deposition to idle, and the controller controls the heater to increase the temperature in the third pipe in order to increase the vapor pressure of the evaporating vapor in the third pipe from the second vapor pressure value to the first vapor pressure value when switching from idle to vapor deposition.

In embodiments of the present disclosure, there is a thermal insulating layer disposed between the cooler and the heater.

In embodiments of the present disclosure, the heater is an electric heating wire that coils around the third pipe.

In embodiments of the present disclosure, the cooler includes an overtube and a refrigerant, the overtube is sleeved on outside the thermal insulating layer, and a gap between an inner wall of the overtube and an outer wall of the thermal insulating layer accommodates the refrigerant.

In embodiments of the present disclosure, the overtube has an air inlet for allowing the refrigerant to flow in and an air outlet for allowing the refrigerant to flow outward.

In embodiments of the present disclosure, the overtube has a flow valve, the flow valve is disposed in the overtube for controlling a flow rate of the refrigerant in the overtube.

In embodiments of the present disclosure, the first pipe, the second pipe, and the third pipe are disposed coaxially and are cylindrical structures, and a width of a channel of the third pipe is less than widths of channels of the first pipe and the second pipe.

In embodiments of the present disclosure, the vapor deposition section has a wall, the wall has an injection port, and the injection port being in communication with the vapor deposition chamber is disposed on the wall for injecting the evaporation vapor in the vapor deposition chamber to the substrate.

In embodiments of the present disclosure, the injection port is a cylindrical structure.

In embodiments of the present disclosure, the vapor deposition chamber of the vapor deposition section has a crucible disposed therein, the crucible is configured for accommodating the vapor deposition material.

Compared to the existing vapor deposition device, the vapor deposition device of the embodiment of the present disclosure includes an evaporation section, a transmission pipe, and a vapor deposition section. The evaporation section is configured to heat vapor deposition material to form evaporating vapor in an evaporation chamber of the evaporation section. The transmission pipe is configured to transmit the evaporating vapor formed in the evaporation chamber to a vapor deposition chamber of the vapor deposition section. The vapor deposition section is configured to deposit the evaporating vapor accumulated in the vapor deposition chamber onto a substrate. The transmission pipe includes a first pipe, a second pipe, and a third pipe. An end of the first pipe is in communication with the evaporation chamber of the evaporation section. A first temperature controlling component is disposed on the first pipe for maintaining a constant temperature in the first pipe. An end of the second pipe is in communication with the vapor deposition chamber of the vapor deposition section. A second temperature controlling component is disposed on the second pipe for maintaining a constant temperature in the second pipe. The third pipe is in communication with another end of the first pipe and another end of the second pipe. A vapor pressure controlling component is disposed on the third pipe. The vapor pressure controlling component is configured for controlling a vapor pressure of the evaporating vapor in the third pipe to decrease when switching from vapor deposition to idle, and the vapor pressure controlling component is configured for controlling the vapor pressure of the evaporating vapor in the third pipe to increase when switching from idle to vapor deposition. The vapor pressure controlling component is disposed on the transmission pipe to control the vapor pressure of the evaporating vapor in the third pipe to decrease when switching from vapor deposition to idle in order to slow down the evaporation rate of the vapor deposition material, so that the evaporation of the vapor deposition material decreases at idle, thereby reducing the loss of the vapor deposition material and improving material utilization.

For more clearly and easily understanding above content of the present disclosure, the following text will take a preferred embodiment of the present disclosure with reference to the accompanying drawings for detailed description as follows.

### DESCRIPTION OF THE DRAWINGS

The technical solution, as well as beneficial advantages, of the present disclosure will be apparent from the following detailed description of one or more embodiments of the present disclosure, with reference to the attached drawings. In the drawings:

FIG. 1 is a schematic perspective view illustrating a first vapor deposition device according to a preferred embodiment of the present disclosure.

FIG. 2 is a schematic perspective view illustrating a second vapor deposition device according to a preferred embodiment of the present disclosure.

FIG. 3 is a cross-sectional view showing the vapor deposition device along the line P1-P1 in FIG. 2.

FIG. 4 is a partial schematic perspective view showing the vapor deposition device in FIG. 2.

FIG. 5 is a cross-sectional view showing the vapor deposition device along the line P2-P2 in FIG. 4.

FIG. 6 is another cross-sectional view showing the vapor deposition device along the line P2-P2 in FIG. 4.

FIG. 7 is still another cross-sectional view showing the vapor deposition device along the line P2-P2 in FIG. 4.

### DETAILED DESCRIPTION OF THE PREFERRED EMBODIMENTS

The embodiments described herein, with reference to the accompanying drawings, are explanatory, illustrative, and used to generally understand the present disclosure. Furthermore, directional terms described by the present disclosure, such as upper, lower, front, rear, left, right, inner, outer, side, etc., are only directions by referring to the accompanying drawings, and thus the used directional terms are used to describe and understand the present disclosure, but the present disclosure is not limited thereto.

In the drawings, modules with similar structures are labeled with the same reference number.

In addition, terms such as “first” and “second” are used herein for purposes of description and are not intended to indicate or imply relative importance or significance. In the description of the present disclosure, “a plurality of” relates to two or more than two. Furthermore, the terms “including” and “having” and any deformations thereof are intended to cover non-exclusive inclusion.

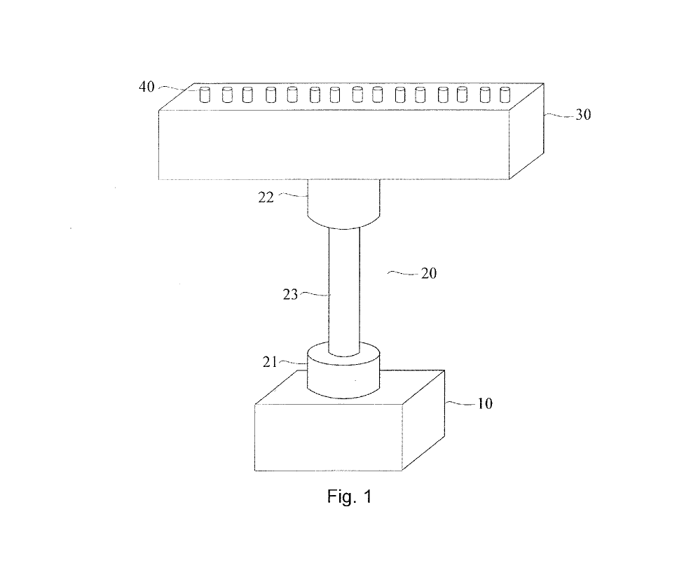

Referring now to FIG. 1, a vapor deposition device according to a preferred embodiment of the present disclosure is illustrated. As shown in FIG. 1, the vapor deposition device of the preferred embodiment includes an evaporation section 10, a transmission pipe 20, and a vapor deposition section 30.

In the embodiment of the present disclosure, the evaporation section 10 is in communication with the transmission pipe 20, the vapor deposition section 30, and an injection port 40 sequentially. The evaporation section 10 is configured to heat vapor deposition material to form evaporating vapor in an evaporation chamber 11 of the evaporation section 10. The transmission pipe 20 is configured to transmit the evaporating vapor formed in the evaporation chamber 11 to a vapor deposition chamber 31 of the vapor deposition section 30. The vapor deposition section 30 is configured to deposit the evaporating vapor accumulated in the vapor deposition chamber 31 onto a substrate.

In some embodiments, the vapor deposition chamber 11 of the vapor deposition section 10 has a crucible disposed therein, where the crucible is configured for accommodating the vapor deposition material. A heating wire is disposed in the crucible to heat the vapor deposition material to form evaporation vapor. The vapor deposition material is crystalline.

Specifically, the vapor deposition section 30 has a wall 32, the wall 32 has the injection port 40, and the injection port 40 in communication with the vapor deposition chamber 31 is disposed on the wall 32 for injecting the evaporation vapor in the vapor deposition chamber 31 to the substrate. As shown in FIG. 1, the injection port 40 is a cylindrical structure. In practice, the injection port 40 may also be a slit disposed along the wall 32.

In the embodiment, the transmission pipe 20 includes a first pipe 21, a second pipe 22, and a third pipe 23. The first pipe 21 is in communication with the third pipe 23 and the second pipe 22 sequentially. Referring to FIGS. 1 to 3, the first pipe 21, the second pipe 22, and the third pipe 23 may be disposed coaxially and are cylindrical structures. A width of a channel of the third pipe 23 is less than widths of channels of the first pipe 21 and the second pipe 22. In practice, the channel of the third pipe 23 may be designed as an elongated area with less thermal capacity.

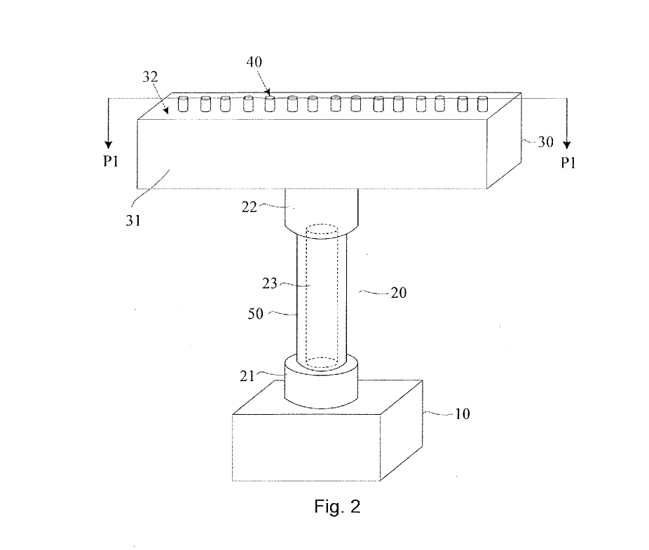

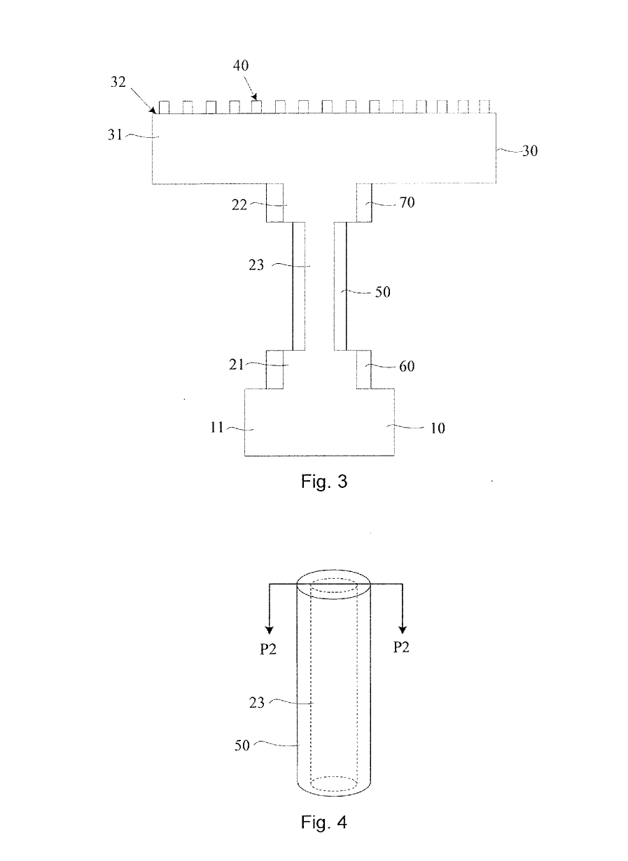

Referring to FIGS. 2 and 3, specifically, an end of the first pipe 21 is in communication with the evaporation chamber 11 of the evaporation section 10. A first temperature controlling component 60 is disposed on the first pipe 21 for maintaining a constant temperature in the first pipe 21. An end of the second pipe 22 is in communication with the vapor deposition chamber 31 of the vapor deposition section 30. A second temperature controlling component 70 is disposed on the second pipe 22 for maintaining a constant temperature in the second pipe 22.

The first temperature controlling component 60 and the second temperature controlling component 70 may include a heating device, a cooling device, a temperature monitoring device, etc., and the temperature of each part is precisely controlled by the temperature controlling system. In practice, the heating device, the cooling device, and the temperature monitoring device may also be independently disposed on the evaporation section 10 and the vapor deposition section 30.

The third pipe 23 is in communication with another end of the first pipe 21 and another end of the second pipe 22. A vapor pressure controlling component 50 is disposed on the third pipe 23. The vapor pressure controlling component 50 is configured for controlling vapor pressure of the evaporating vapor in the third pipe 23 to decrease when switching from vapor deposition to idle, and the vapor pressure controlling component 50 is configured for controlling the vapor pressure of the evaporating vapor in the third pipe 23 to increase when switching from idle to vapor deposition.

The arrangements of the vapor pressure controlling component 50 may be multiple. For example, as shown in FIG. 3, the vapor pressure controlling component 50 may cover the outer wall surface of the third pipe 23.

Referring to FIGS. 4 and 5, in some embodiments of the present disclosure, the vapor pressure controlling component 50 includes a controller, a cooler 51, and a heater 52. The controller electrically connects to the cooler 51 and the heater 52. The controller can be disposed in the corresponding position according to the actual situation.

Specifically, the controller controls the cooler 51 to decrease temperature in the third pipe 23 in order to decrease the vapor pressure of the evaporating vapor in the third pipe 23 from a first vapor pressure value to a second vapor pressure value when switching from vapor deposition to idle, and the controller controls the heater 52 in order to increase the temperature in the third pipe 23 to increase the vapor pressure of the evaporating vapor in the third pipe 23 from the second vapor pressure value to the first vapor pressure value when switching from idle to vapor deposition.

Referring to FIGS. 4 and 5, in some embodiments of the present disclosure, the heater 52 covers an outer wall of the third pipe 23, and the cooler 51 covers the heater 52. The heater 52 may be an electric heating wire that coils around the third pipe 23.

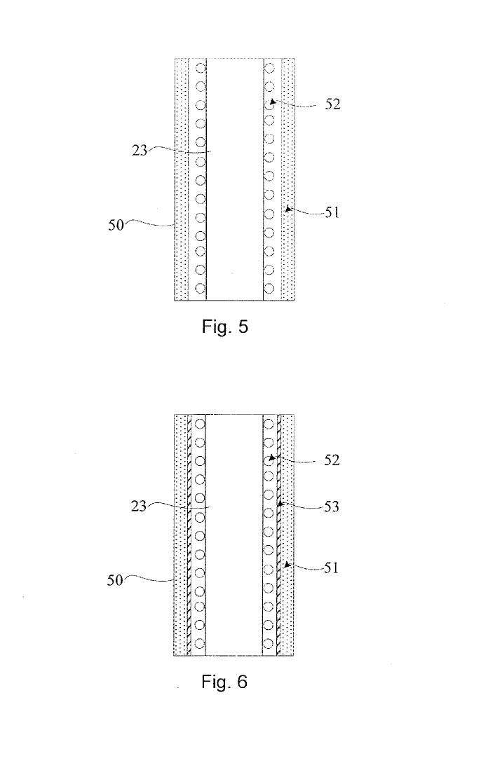

Referring to FIG. 6, in some embodiments of the present disclosure, there is a thermal insulating layer 53 disposed between the cooler 51 and the heater 52.

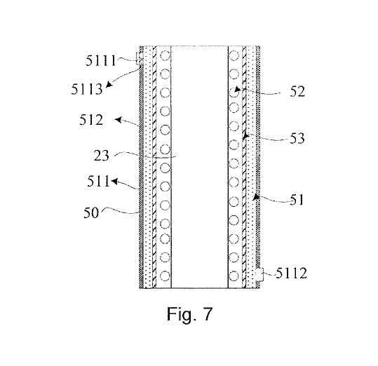

Referring to FIG. 7, in some embodiments of the present disclosure, the cooler 51 includes an overtube 511 and a refrigerant 512. The overtube 511 is sleeved on outside the thermal insulating layer 53, and a gap between an inner wall of the overtube 511 and an outer wall of the thermal insulating layer 53 accommodates the refrigerant 512. In practice, the refrigerant 512 may be water, FREON, etc.

Referring to FIG. 7, the overtube 511 has an air inlet 5111 for allowing the refrigerant 512 to flow in and an air outlet 5112 for allowing the refrigerant 512 to flow outward. The overtube 511 has a flow valve 5113. The flow valve 5113 is disposed in the overtube 511 for controlling a flow rate of the refrigerant 512 in the overtube.

Specifically, when the vapor deposition device is switched from vapor deposition to idle, the controller controls the vapor pressure of the evaporating vapor in the vapor pressure controlling area (that is, the third pipe 23).

In the vapor pressure controlling component 50, the controller controls the heater 52 to reduce the thermal capacity while controlling the cooler 51 to increase the flow rate of the refrigerant 512 to enhance the cooling capacity of the cooler 51 and to reduce the vapor pressure of the evaporating vapor passing through the third pipe 23. The temperature in the third pipe 23 is maintained to be within the temperature range where the evaporating vapor cannot be deposited to control the overall evaporation rate of the vapor deposition material, thereby reducing the transmission rate of transmitting the vapor deposition material from the evaporation section 10 to the vapor deposition section 30. The evaporation rate of the vapor deposition material is controlled in real time by the rate monitoring device, and the evaporation rate is reduced to a low level. For example, the quartz crystal microbalance (QCM) can be used to detect the change in mass of the vapor deposition material to calculate the evaporation rate for real-time monitoring.

The first pipe 21, the second pipe 22, and the vapor deposition section 30 maintain a constant temperature control mode in which the evaporation section 10 is switched to the constant temperature control mode and the temperature in the third pipe 23 is reduced to form a temperature gradient. For example, the temperature in the third pipe 23 is the lowest, the temperature in the first pipe 21 is greater than the temperature in the evaporation section 10, and the temperature of the second pipe 22 is not greater than the temperature of the vapor deposition section 30. The temperatures in the first pipe 21 and the second pipe 22 are greater than the temperature at the time of vapor deposition to ensure that the low temperature in the third pipe 23 does not affect the temperature in the vapor deposition section 30 and the evaporation section 10. In this process, the temperature can be controlled by a proportion integral derivative (PID) control system.

In addition, before the idle mode is completed, the vapor pressure control mode needs to be released to restore the control mode of constant evaporation rate of the vapor deposition device.

In the vapor pressure controlling component 50, the controller controls the heater 52 to increase the thermal capacity while controlling the cooler 51 not to increase the amount of the refrigerant 512 in order to increase the vapor pressure of the evaporating vapor passing through the third pipe 23. Since the vapor pressure is increased for a certain period of time, the temperature of the evaporation chamber 11 is increased by the heating device of the evaporation section 10 before the normal vapor pressure is reached. Through the PID control system accurately controlling the regional temperature, the evaporation rate can be quickly returned to the original normal level to implement the coating.

As described above, the vapor deposition device of the embodiment of the present disclosure includes an evaporation section, a transmission pipe, and a vapor deposition section. The evaporation section is configured to heat vapor deposition material to form evaporating vapor in an evaporation chamber of the evaporation section. The transmission pipe is configured to transmit the evaporating vapor formed in the evaporation chamber to a vapor deposition chamber of the vapor deposition section. The vapor deposition section is configured to deposit the evaporating vapor accumulated in the vapor deposition chamber onto a substrate. The transmission pipe includes a first pipe, a second pipe, and a third pipe. An end of the first pipe is in communication with the evaporation chamber of the evaporation section. A first temperature controlling component is disposed on the first pipe for maintaining a constant temperature in the first pipe. An end of the second pipe is in communication with the vapor deposition chamber of the vapor deposition section. A second temperature controlling component is disposed on the second pipe for maintaining a constant temperature in the second pipe. The third pipe is in communication with another end of the first pipe and another end of the second pipe. A vapor pressure controlling component is disposed on the third pipe. The vapor pressure controlling component is configured for controlling a vapor pressure of the evaporating vapor in the third pipe to decrease when switching from vapor deposition to idle, and the vapor pressure controlling component is configured for controlling the vapor pressure of the evaporating vapor in the third pipe to increase when switching from idle to vapor deposition. The vapor pressure controlling component is disposed on the transmission pipe to control the vapor pressure of the evaporating vapor in the third pipe to decrease when switching from vapor deposition to idle in order to slow down the evaporation rate of the vapor deposition material, so that the evaporation of the vapor deposition material decreases at idle, thereby reducing the loss of the vapor deposition material and improving material utilization.

The present disclosure has been described with a preferred embodiment thereof. The preferred embodiment is not intended to limit the present disclosure, and it is understood that many changes and modifications to the described embodiment can be carried out without departing from the scope and the spirit of the invention that is intended to be limited only by the appended claims.

What is claimed is:

1. A vapor deposition device, wherein the vapor deposition device comprises an evaporation section, a transmission pipe, and a vapor deposition section, the evaporation section is configured to heat vapor deposition material to form evaporating vapor in an evaporation chamber of the evaporation section, the transmission pipe is configured to transmit the evaporating vapor formed in the evaporation chamber to a vapor deposition chamber of the vapor deposition section, the vapor deposition section is configured to deposit the evaporating vapor accumulated in the vapor deposition chamber onto a substrate;
the transmission pipe comprises a first pipe, a second pipe, and a third pipe;
an end of the first pipe being in communication with the evaporation chamber of the evaporation section, wherein a first temperature controlling component is disposed on the first pipe for maintaining a constant temperature in the first pipe;
an end of the second pipe being in communication with the vapor deposition chamber of the vapor deposition section, wherein a second temperature controlling component is disposed on the second pipe for maintaining a constant temperature in the second pipe; and
the third pipe being in communication with another end of the first pipe and another end of the second pipe, a vapor pressure controlling component being disposed on the third pipe, wherein the vapor pressure controlling component is configured for controlling vapor pressure of the evaporating vapor in the third pipe to decrease when switching from vapor deposition to idle, and the vapor pressure controlling component is configured for controlling the vapor pressure of the evaporating vapor in the third pipe to increase when switching from idle to vapor deposition.

2. The vapor deposition device according to claim 1, wherein the vapor pressure controlling component comprises a controller, a cooler, and a heater, the controller electrically connects to the cooler and the heater, the controller controls the cooler to decrease temperature in the third pipe in order to decrease the vapor pressure of the evaporating vapor in the third pipe from a first vapor pressure value to a second vapor pressure value when switching from vapor deposition to idle, and the controller controls the heater to increase the temperature in the third pipe in order to increase the vapor pressure of the evaporating vapor in the third pipe from the second vapor pressure value to the first vapor pressure value when switching from idle to vapor deposition.

3. The vapor deposition device according to claim 2, wherein the heater covers an outer wall of the third pipe, and the cooler covers the heater.

4. The vapor deposition device according to claim 3, wherein there is a thermal insulating layer disposed between the cooler and the heater.

5. The vapor deposition device according to claim 3, wherein the heater is an electric heating wire that coils around the third pipe.

6. The vapor deposition device according to claim 4, wherein the cooler comprises an overtube and a refrigerant, the overtube is sleeved on outside the thermal insulating layer, and a gap between an inner wall of the overtube and an outer wall of the thermal insulating layer accommodates the refrigerant.

7. The vapor deposition device according to claim 6, wherein the overtube has an air inlet for allowing the refrigerant to flow in and an air outlet for allowing the refrigerant to flow outward.

8. The vapor deposition device according to claim 7, wherein the overtube has a flow valve, the flow valve is disposed in the overtube for controlling a flow rate of the refrigerant in the overtube.

9. The vapor deposition device according to claim 1, wherein the first pipe, the second pipe, and the third pipe are disposed coaxially and are cylindrical structures, and a width of a channel of the third pipe is less than widths of channels of the first pipe and the second pipe.

10. The vapor deposition device according to claim 1, wherein the vapor deposition section has a wall, the wall has an injection port, the injection port in communication with the vapor deposition chamber is disposed on the wall for injecting the evaporation vapor in the vapor deposition chamber to the substrate.

11. A vapor deposition device, wherein the vapor deposition device comprises an evaporation section, a transmission pipe, and a vapor deposition section, the evaporation section is configured to heat vapor deposition material to form evaporating vapor in an evaporation chamber of the evaporation section, the transmission pipe is configured to transmit the evaporating vapor formed in the evaporation chamber to a vapor deposition chamber of the vapor deposition section, the vapor deposition section is configured to deposit the evaporating vapor accumulated in the vapor deposition chamber onto a substrate;
the transmission pipe comprising a first pipe, a second pipe, and a third pipe;
an end of the first pipe being in communication with the evaporation chamber of the evaporation section, wherein a first temperature controlling component is disposed on the first pipe for maintaining a constant temperature in the first pipe;
an end of the second pipe being in communication with the vapor deposition chamber of the vapor deposition section, wherein a second temperature controlling component is disposed on the second pipe for maintaining a constant temperature in the second pipe;
the third pipe in communication with another end of the first pipe and another end of the second pipe, a vapor pressure controlling component being disposed on the third pipe, wherein the vapor pressure controlling component comprises a controller, a cooler, and a heater, the controller electrically connects to the cooler and the heater, the heater covers an outer wall of the third pipe, and the cooler covers the heater; and
wherein the controller controls the cooler to decrease a temperature in the third pipe in order to decrease the vapor pressure of the evaporating vapor in the third pipe from a first vapor pressure value to a second vapor pressure value when switching from vapor deposition to idle, and the controller controls the heater to increase the temperature in the third pipe in order to increase the vapor pressure of the evaporating vapor in the third pipe from the second vapor pressure value to the first vapor pressure value when switching from idle to vapor deposition.

12. The vapor deposition device according to claim 11, wherein there is a thermal insulating layer disposed between the cooler and the heater.

13. The vapor deposition device according to claim 12, wherein the heater is an electric heating wire that coils around the third pipe.

14. The vapor deposition device according to claim 13, wherein the cooler comprises an overtube and a refrigerant, the overtube is sleeved on outside the thermal insulating layer, and a gap between an inner wall of the overtube and an outer wall of the thermal insulating layer accommodates the refrigerant.

15. The vapor deposition device according to claim 14, wherein the overtube has an air inlet for allowing the refrigerant to flow in and an air outlet for allowing the refrigerant to flow outward.

16. The vapor deposition device according to claim 15, wherein the overtube has a flow valve, the flow valve is disposed in the overtube for controlling a flow rate of the refrigerant in the overtube.

17. The vapor deposition device according to claim 11, wherein the first pipe, the second pipe, and the third pipe are disposed coaxially and are cylindrical structures, and a width of a channel of the third pipe is less than widths of channels of the first pipe and the second pipe.

18. The vapor deposition device according to claim 11, wherein the vapor deposition section has a wall, the wall has an injection port, the injection port being in communication with the vapor deposition chamber is disposed on the wall for injecting the evaporation vapor in the vapor deposition chamber to the substrate.

19. The vapor deposition device according to claim 18, wherein the injection port is a cylindrical structure.

20. The vapor deposition device according to claim 11, wherein the vapor deposition chamber of the vapor deposition section has a crucible disposed therein, and the crucible is configured for accommodating the vapor deposition material.
